(19) United States
(12) Patent Application Publication
(10) Pub. No.: US 2020/0150535 A1
(43) Pub. Date: May 14, 2020

(54) PROCESS FOR CONTROLLING THE ORIENTATION OF THE NANODOMAINS OF A BLOCK COPOLYMER

(71) Applicant: Arkema France, Columbes (FR)

(72) Inventor: Xavier Chevalier, Grenoble (FR)

(73) Assignee: Arkema France, Colombes (FR)

(21) Appl. No.: 16/631,093

(22) PCT Filed: Jul. 20, 2018
(86) PCT No.: PCT/FR2018/051857

§ 371 Date: Jan. 14, 2020

(30) Foreign Application Priority Data
Jul. 21, 2017 (FR) 1756928

(51) Int. Cl. G03F 7/16; G03F 7/00

(52) U.S. Cl. CPC G03F 7/16; G03F 7/0002

(57) ABSTRACT

The invention relates to a process for controlling the orientation of the nanodomains of a block copolymer (BCP), the lower interface of which is in contact with the surface, neutralized beforehand, of a substrate, the said block copolymer being capable of nanostructuring itself to give nanodomains with a predetermined period (L₀), over a minimum thickness (t) at least equal to half of the said period (L₀), the said process being characterized in that it consists in depositing the said block copolymer (BCP) on the said substrate, so that its total thickness (T+t) is at least two times greater and preferably at least three times greater than the said minimum thickness (t), and in then depositing, on the said block copolymer (BCP), an interface material which makes it possible to isolate it from the ambient atmosphere.

### FIELD OF THE INVENTION

The present invention relates to the field of the control of the orientation of the nanodomains of a block copolymer, which are generated during the nanostructuring of the said block copolymer. This orientation depends in particular on the surface energy at each interface of the block copolymer.

More particularly, the invention relates to a process for controlling the orientation of the nanodomains of a block copolymer, the upper interface of which is in contact with a compound, or mixture of compounds, in the liquid or solid form. In addition, the invention relates to a process for the manufacture of a nanolithography resist starting from a block copolymer, the said process comprising the stages of the process for controlling the orientation of the blocks of the said block copolymer.

### PRIOR ART

The development of nanotechnologies has made it possible to constantly miniaturize products in the field of microelectronics and micro-electro-mechanical systems (MEMS) in particular. At the current time, conventional lithography techniques no longer make it possible to meet these constant needs for miniaturization, as they do not make it possible to produce structures with dimensions of less than 60 nm.

It has therefore been necessary to adapt the lithography techniques and to create etching resists which make it possible to create increasingly small patterns with a high resolution. With block copolymers, it is possible to structure the arrangement of the constituent blocks of the copolymers by phase segregation between the blocks, thus forming nanodomains, at scales of less than 50 nm. Due to this ability to be nanostructured, the use of block copolymers in the fields of electronics or optoelectronics is now well known.

However, the block copolymers intended to form nanolithography resists have to exhibit nanodomains oriented perpendicularly to the surface of the substrate, in order to be able subsequently to selectively remove one of the blocks of the block copolymer and to create a porous film with the residual block(s). The patterns thus created in the porous film can subsequently be transferred, by etching, to an underlying substrate.

The surface energy (denoted γₓ) of a given material “x” is defined as being the excess energy at the surface of the material in comparison with that of the material within its body. When the material is in the liquid form, its surface energy is equivalent to its surface tension.

Each of the blocks i, . . . j of a block copolymer exhibits a surface energy, denoted γᵢ . . . γⱼ, which is specific to it and which depends on its chemical constituents, that is to say on the chemical nature of the monomers or comonomers of which it is composed. Likewise, each of the constituent materials of a substrate exhibits its own surface energy value.

Each of the blocks i, . . . j of the block copolymer exhibits, in addition, an interaction parameter of Flory-Huggins type, denoted: χᵢₓ, when it interacts with a given material “x”, which can be a liquid, a solid surface or another polymer phase, for example, and an interfacial energy denoted “γᵢₓ”, with γᵢₓ=γᵢ−(γₓ cos θᵢₓ), where θᵢₓ is the contact angle between the materials i and x. The interaction parameter between two blocks i and j of the block copolymer is thus denoted χᵢⱼ.

Jia et al., Journal of Macromolecular Science, B, 2011, 50, 1042, have shown that there exists a relationship connecting the surface energy γᵢ and the Hildebrand solubility parameter δᵢ of a given material i. In fact, the Flory-Huggins interaction parameter between two given materials i and x is indirectly related to the surface energies γᵢ and γₓ specific to the materials. The physical phenomenon of interaction appearing at the interface of the materials is thus described either in terms of surface energies or in terms of interaction parameter.

In order to obtain a structuring of the constituent nanodomains of a block copolymer which is perfectly perpendicular with respect to the underlying substrate, it thus appears necessary to precisely control the interactions of the block copolymer with the different interfaces with which it is physically in contact. In general, the block copolymer is in contact with two interfaces: an interface referred to as “lower” in the continuation of the description, in contact with the underlying substrate, and an interface referred to as “upper”, in contact with another compound or mixture of compounds. In general, the compound or mixture of compounds at the upper interface is composed of ambient air or of an atmosphere of controlled composition. However, it can more generally be composed of any compound or mixture of compounds of defined molecular constitution and of defined surface energy, whether it is solid or liquid, that is to say non-volatile, at the temperature of self-organization of the nanodomains.

When the surface energy of each interface is not controlled, there is generally a specific orientation of the patterns of the block copolymer and more particularly an orientation parallel to the substrate, this being the case whatever the morphology of the block copolymer. This parallel orientation is mainly due to the fact that the substrate and/or the compound(s) at the upper interface exhibit a preferred affinity with one of the constituent blocks of the block copolymer at the self-organization temperature of the said block copolymer. In other words, the interaction parameter of Flory-Huggins type of a block i of the block copolymer with the underlying substrate, denoted χ_{i-substrate}, and/or the interaction parameter of Flory-Huggins type of a block i of the block copolymer with the compound at the upper interface, for example air, denoted χᵢ₋ₐᵢᵣ, is much less than zero or greater than zero, and the interfacial energies γ_{i-substrate} and/or γᵢ₋ₐᵢᵣ are not equivalent to one another.

Consequently, the desired structuring, that is to say the generation of domains perpendicular to the surface of the substrate, the patterns of which may be cylindrical, lamellar, helical or spherical, for example, requires control of the surface energies not only at the lower interface, that is to say at the interface with the underlying substrate, but also at the upper interface.

In the context of the use of the block copolymers as nanostructured resists for applications in microelectronics (lithography, memory point, waveguide, and the like), the aim is to guide the orientation of the different blocks of a given block copolymer by means of a predefined pattern produced beforehand on the underlying substrate.

There exist two main techniques which make it possible to control and guide the orientation of the blocks of a block copolymer on a substrate: graphoepitaxy and chemical epitaxy. Graphoepitaxy uses a topological constraint to force the block copolymer to organize itself in a predefined space commensurable with the periodicity of the block copolymer. For this, graphoepitaxy consists in forming primary patterns, known as guides, at the surface of the substrate. These guides, of any chemical affinity with regard to the blocks of the block copolymer, delimit zones inside which a layer of block copolymer is deposited. The guides make it possible to control the organization of the blocks of the block copolymer in order to form secondary patterns of higher resolution, inside these zones. Conventionally, the guides are formed by photolithography.

The surface of the substrate located between the guides can, in addition, be neutralized in order for the surfaces in contact with the block copolymer deposited subsequently not to exhibit a preferred affinity with one of the blocks. For this, Mansky et al., in Science, Vol. 275, pages 1458-1460 (7 Mar. 1997), have for example shown that a statistical poly(methyl methacrylate-co-styrene) (PMMA-r-PS) copolymer, functionalized by a hydroxyl functional group at the chain end, makes possible good grafting of the copolymer at the surface of a silicon substrate exhibiting a layer of native oxide (Si/native SiO₂) and makes it possible to obtain a surface energy which is non-preferential for the blocks of the block copolymer to be nanostructured. The key point of this approach is the obtaining of a grafted layer, making it possible to act as barrier with regard to the specific surface energy of the substrate. The interfacial energy of this barrier with a given block of the block copolymer is equivalent for each of the blocks i . . . j of the block copolymer and is modulated by the ratio of the comonomers present in the grafted statistical copolymer. The grafting of such a statistical copolymer thus makes it possible to suppress the preferred affinity of one of the blocks of the block copolymer for the surface of the substrate and to thus prevent a preferred orientation of the nanodomains parallel to the surface of the substrate from being obtained. The grafting reactions can be obtained by any known means (thermal, photochemical, oxidation/reduction, and the like).

The chemical epitaxy uses, for its part, a contrast in chemical affinities between a pattern pre-drawn on the substrate and the different blocks of the block copolymer. Thus, a pattern exhibiting a high affinity for just one of the blocks of the block copolymer is pre-drawn at the surface of the underlying substrate, in order to make possible the perpendicular orientation of the blocks of the block copolymer, while the remainder of the surface does not exhibit a specific affinity for the blocks of the block copolymer. For this, a layer comprising, on the one hand, neutral zones (consisting, for example, of grafted statistical copolymer), not exhibiting a specific affinity with the blocks of the block copolymer to be deposited, and, on the other hand, zones with affinity (consisting, for example, of homopolymer grafted with one of the blocks of the block copolymer to be deposited and acting as anchoring point for this block of the block copolymer) is deposited at the surface of the substrate. The homopolymer acting as anchoring point can be produced with a width slightly greater than that of the block with which it has a preferred affinity and makes possible, in this case, a “pseudo-equitable” distribution of the blocks of the block copolymer at the surface of the substrate. Such a layer is said to be “pseudo-neutral” as it makes possible an equitable or “pseudo-equitable” distribution of the blocks of the block copolymer at the surface of the substrate, with the result that the layer does not exhibit, in its overall nature, a preferred affinity with one of the blocks of the block copolymer. Consequently, such a chemically epitaxied layer at the surface of the substrate is considered as being neutral with regard to the block copolymer.

Although the techniques which have just been described make it possible to efficiently guide the self-assembling of the block copolymer along one or more specific directions, they are not sufficient to obtain an orientation of the blocks perfectly perpendicular to the surface of the substrate. This is because, in order to obtain such an orientation perpendicular to the surface of the substrate, over a minimum thickness, it is necessary to be able to generate “neutral” upper and lower interfaces of the film of block copolymer, that is to say where the blocks of the block copolymer do not exhibit preponderant affinities, with respect to one another, with each of the different interfaces.

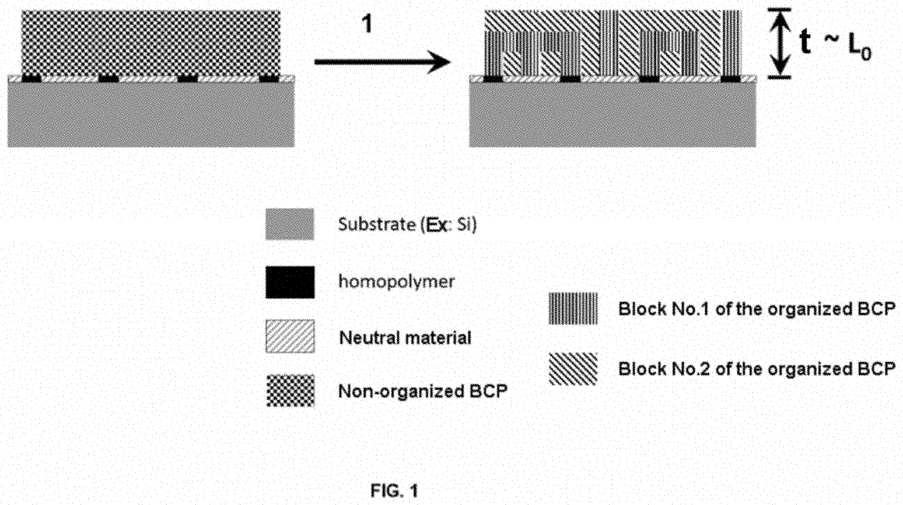

In particular, when one of the blocks of the block copolymer exhibits a preferred affinity for the compound(s) of an interface, the nanodomains then have a tendency to orient themselves parallel to this interface. The diagram of FIG. 1 illustrates the case where the surface energy at the upper interface, between a block copolymer referenced BCP and ambient air in the example, is not controlled, whereas the lower interface, between the underlying substrate and the block copolymer, exhibits a chemically epitaxied pattern, in order to guide the orientation of the blocks, with zones, represented in black in FIG. 1, comprising a homopolymer of one of the blocks of the block copolymer to be deposited, and zones, represented in hatching in FIG. 1, comprising a statistical copolymer which is neutral with regard to the blocks of the block copolymer. The chemically epitaxied surface does not exhibit, in its overall nature, a preferred affinity with one of the blocks of the block copolymer, that is to say that the Flory-Huggins parameter χ_{i-substrate} and χ_{j-substrate} is equivalent for each of the blocks i . . . j of the block copolymer. It is then considered that the surface of the substrate, thus chemically epitaxied, is neutral with regard to the block copolymer. In this case, during the annealing which makes possible the organization of the copolymer (stage referenced 1 in FIG. 1), a layer of one of the blocks i or j of the block copolymer, exhibiting the strongest affinity with the air (in the example of FIG. 1, it is the block No. 2), organizes itself in the upper part of the film of the block copolymer, that is to say at the interface with the air, and orientates itself parallel to this interface. It is then not possible to obtain nanodomains which are perfectly perpendicular to the surface of the substrate over a minimum thickness “t” at least equal to the period L₀ of the copolymer.

In order to obtain a structuring of the nanodomains of a block copolymer which is perfectly perpendicular with respect to the upper and lower interfaces, it is necessary for the interfacial tension between the material at the interface and each of the blocks of the block copolymer to be equivalent.

When the surface energy at the interface of the copolymer is poorly controlled, a significant defectivity due to the non-perfect perpendicularity of the nanodomains of the block copolymer once self-assembled, indeed even a structuring completely parallel to the said interface, then becomes apparent.

While the neutrality of the lower interface between the block copolymer and the underlying substrate is at the current time well controlled, the upper interface between the block copolymer and a compound or mixture of compounds, which is solid or liquid, is markedly less controlled.

However, various approaches, described below, exist for overcoming this, the surface energy at the lower interface between the block copolymer and the underlying substrate being controlled in the three approaches below.

A first solution might consist in carrying out an annealing of the block copolymer in the presence of a gas mixture, making it possible to satisfy the conditions of neutrality with respect to each of the blocks of the block copolymer. However, the composition of such a gas mixture appears very complex to find.

A second solution, when the mixture of compounds at the upper interface is composed of ambient air, consists in using a block copolymer, the constituent blocks of which all exhibit an identical (or very similar) surface energy with respect to one another, at the self-organization temperature. In such a case, the perpendicular organization of the nanodomains of the block copolymer is obtained, on the one hand, by virtue of the block copolymer/neutralized substrate interface and, on the other hand, by virtue of the fact that the blocks i . . . j of the block copolymer BCP naturally exhibit a comparable affinity for the component at the upper interface, in this case the air in the example. The situation is then χ_{i-substrate}˜ . . . ˜ χ_{j-substrate} (=0 preferably) and γᵢ₋ₐᵢᵣ ˜ . . . ˜γⱼ₋ₐᵢᵣ. Nevertheless, there exist only a limited number of block copolymers exhibiting this distinctive feature. This is, for example, the case of the block copolymer PS-b-PMMA. However, the Flory-Huggins interaction parameter for the copolymer PS-b-PMMA is low, that is to say of the order of 0.039, at the temperature of 150° C. of self-organization of this copolymer, which limits the minimum size of the nanodomains generated.

Furthermore, the surface energy of a given material depends on the temperature. In point of fact, if the self-organization temperature is increased, for example when it is desired to organize a block copolymer of high weight or of high period, consequently requiring a great deal of energy in order to obtain a correct organization, it is possible for the difference in surface energy of the blocks to then become too great for the affinity of each of the blocks of the block copolymer for the compound at the upper interface to be able to be still regarded as equivalent. In this case, the increase in the self-organization temperature can then result in the appearance of defects related to the non-perpendicularity of the assembling, as a result of the difference in surface energy between the blocks of the block copolymer at the self-organization temperature.

A final solution envisaged, described by Bates et al. in the publication entitled “Polarity-switching top coats enable orientation of sub-10 nm block copolymer domains”, Science, 2012, Vol. 338, pp 775-779, and in the document US2013 280497, consists in controlling the surface energy at the upper interface of a block copolymer to be nanostructured, of poly(trimethylsilylstyrene-b-lactide) or poly(styrene-b-trimethylsilylstyrene-b-styrene) type, by the introduction of an upper layer, also known as “top coat”, deposited at the surface of the block copolymer. In this document, the top coat, which is polar, is deposited by spin coating on the film of block copolymer to be nanostructured. The top coat is soluble in an acidic or basic aqueous solution, which allows it to be applied to the upper surface of the block copolymer, which is insoluble in water. In the example described, the top coat is soluble in aqueous ammonium hydroxide solution. The top coat is a statistical or alternating copolymer, the composition of which comprises maleic anhydride. In solution, the opening of the ring of the maleic anhydride allows the top coat to lose ammonia. During the self-organization of the block copolymer at the annealing temperature, the ring of the maleic anhydride of the top coat recloses, the top coat undergoes a transformation into a less polar state and becomes neutral with respect to the block copolymer, thus making possible a perpendicular orientation of the nanodomains with respect to the two lower and upper interfaces. The top coat is subsequently removed by washing in an acidic or basic solution.

Likewise, the document US 2014238954A describes the same principle as that of the document US2013 280497 but applied to a block copolymer comprising a block of silsesquioxane type.

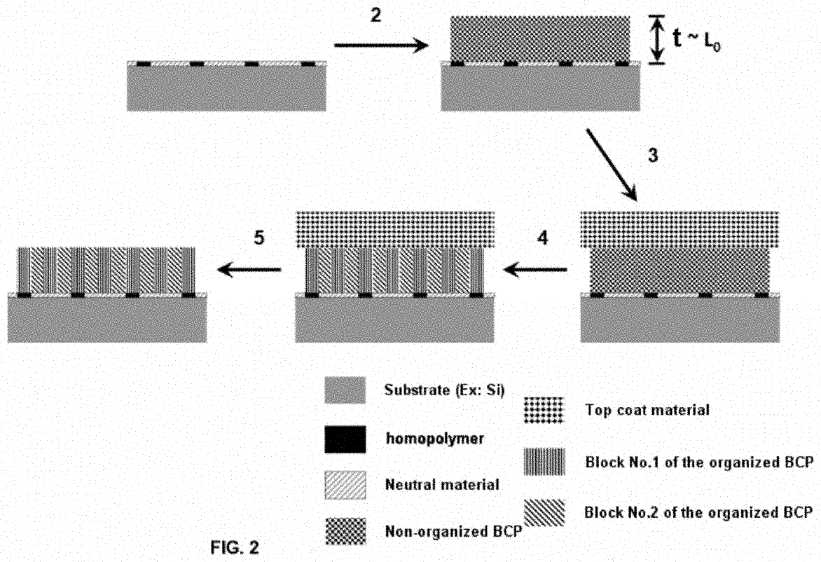

This solution, as illustrated in FIG. 2, makes it possible to replace the upper interface between the block copolymer BCP to be organized and a compound or mixture of compounds, which is gaseous, solid or liquid, with a block copolymer-top coat interface. In the stage referenced 2, the block copolymer is deposited on the surface of the substrate neutralized beforehand by producing a chemically epitaxied pattern. The block copolymer BCP is deposited over a thickness “t” of the order of the period L₀ of the copolymer. Then, in stage 3, the top coat is deposited. An annealing is then carried out in stage 4 in order to nanostructure the block copolymer BCP. Finally, as soon as the block copolymer is organized, the top coat is removed in stage 5, so as to retain a film of nanostructured block copolymer with nanodomains perfectly perpendicular to the surface of the substrate and over its entire thickness “t”. In this case, the material of the top coat exhibits an equivalent affinity for each of the blocks i . . . j of the block copolymer BCP at the assembling temperature considered (χ_{i-TC}= . . . =χ_{j-TC} (=˜0 preferably)).

The comparison of FIGS. 1 and 2 illustrates the advantage of using a top coat layer (FIG. 2) when a block copolymer, one of the blocks (block No. 2) of which exhibits a preferred affinity with the ambient atmosphere (FIG. 1), is guided via a chemical epitaxy. It is clearly apparent that the top coat layer makes it possible, during stage 4 of nanostructuring by annealing, to orientate the nanodomains of the block copolymer, perpendicularly to the surface of the substrate, over the entire thickness “t” of the film of block copolymer BCP. This film thickness “t” is at least of the order of a period (“L₀”) of the block copolymer in order to be able subsequently to transfer the patterns into the substrate. If the top coat layer is not used (as illustrated in FIG. 1), the film of block copolymer is not at all homogeneous in its thickness “t”, that is to say that the perpendicularity of the nanodomains in the minimum thickness “t” is not reached because of the preferred affinity of the block No. 2 for the ambient atmosphere.

However, the use of a top coat layer and also its design and its incorporation in the overall scheme for the assembling of the block copolymer presents several fundamental problems which are complex to solve. A first difficulty lies in the deposition of the top coat layer itself. Thus, during its deposition, it is essential for the constituent material of the top coat layer to be soluble in a solvent in which the block copolymer itself is not soluble, if the block copolymer deposited beforehand on the substrate is not to be again dissolved. It is also necessary for the top coat layer to be able to be easily removed, for example by rinsing in an appropriate solvent, preferably itself compatible with the standard items of equipment of electronics. Moreover, the top coat layer must exhibit an equivalent interfacial tension for each of the different blocks of the block copolymer to be nanostructured, during the heat treatment. In view of all these difficulties, the chemical synthesis of the top coat material may prove to be a challenge in itself. Mention may also be made of potential problems of thermal stability of the top coat layer, and also the density of the top coat material, which should preferably be lower than that of the block copolymer. Consequently, even if a few solutions exist for generating a top coat system for a block copolymer of given chemistry, in all cases, the process of guiding, of orienting and of nanostructuring the blocks of the block copolymer, for the purpose of obtaining a pattern advantageous for the targeted nanolithography applications, is found to be consequently complicated thereby, to the detriment of the simplicity of use of the block copolymers for such applications.

Be that as it may, the use of a top coat layer appears to be a priori essential for orienting the nanodomains of a block copolymer perpendicularly with respect to the substrate, all the more so when the block copolymer in question is guided through techniques such as graphoepitaxy or chemical epitaxy, as otherwise the efforts made to produce the pattern on the substrate for the purpose of guiding the block copolymer would be rendered pointless.

The different approaches described above for controlling the surface energy at the upper interface of a block copolymer deposited on a substrate, the surface of which was neutralized beforehand, generally remain too tedious and complex to implement and do not make it possible to significantly reduce the defectivity related to the non-perfect perpendicularity of the patterns of the block copolymer. In addition, the solutions envisaged appear too complex to be able to be compatible with industrial applications.

In parallel with these different technical problems, quite another category of problems of producing films of block copolymers BCP exhibiting an acceptable content of defects (due to poor perpendicularity, or to grain boundaries, and the like) for applications targeted in the field of electronics lies in the control of the properties of “wetting” and/or of adhesion of the said film to the substrate. This is because numerous studies, reported in the papers by T. P. Russell et al., Macromolecules, 2017, 50 (12), 4597-4609; M. Geoghegan et al., Prog. Polym. Sci., 2003, 28, 261-302; P. G. de Gennes, Rev. Mod. Phys., 1985, 57, 827-863, have shown that the quality (homogeneity, continuity) of a film of any material, such as a polymer, for example, deposited on a given substrate, depends on different parameters internal to the material/substrate system under consideration. These parameters include in particular the surface energies and interfacial tension of each component of the system, the temperature, the thickness of the film, or else the very nature of these components (solid, liquid, molecular constitution, and the like). Generally, it is thus widely accepted that substrates exhibiting low surface energies are difficult to “wet”/adhere. Consequently, a polymer film on this type of substrate will instead have a tendency to be strongly non-homogeneous in thickness, this being all the more the case when the said polymer is left free to change after deposition, for example during a thermal heating above the glass transition temperature of the polymer. In the same way, the more the polymer film deposited is thin, that is to say at least one times the radius of gyration of a molecular chain of the polymer under consideration, the more it will have a tendency to be unstable or metastable, all the more so when the surface energy of the substrate is different from that of the said polymer and when the system is left free to change. Finally, the instability of the polymer film deposited on the substrate generally increases as the “annealing temperature/annealing time” pair increases.

In fact, when these different points are confronted with a dedicated block copolymer BCP system, for the purpose of applications for electronics, or for another field necessarily requiring a continuous film of block copolymer BCP over a minimum surface area of a substrate, the said block copolymer being deposited along the minimum thickness “t”, it becomes risky to be able to combine a high-temperature annealing, in order to decrease the potential assembling defects, when the film of block copolymer BCP is deposited on a substrate functionalized so that the interfacial energies of the blocks versus that of the solid surface are balanced for all the blocks (in other words, that each block of the BCP “sees” a substrate, the surface energy of which is different from its own). This type of dewetting phenomena has, for example, been reported for block copolymers such as PS-b-PMMA (R. A. Farrell et al., ACS Nano, 2011, 5, 1073-1085), whereas the PS and PMMA blocks of these block copolymers exhibit relatively high surface energies. In point of fact, the films based on these block copolymers are supposed to be more stable with regard to the dewetting than those based on block copolymers, the blocks of which would exhibit lower surface energies.

Consequently, in the context of the use of the block copolymers BCP in the form of thin films, such as, for example, as lithography resists, it is essential not only to be able to control the affinity of the upper interface, in order to guarantee the perpendicularity of the patterns with respect to the substrate, but also to be able to guarantee that the film of block copolymer BCP indeed covers all the surface of the substrate under consideration without dewetting of the surface, and also to guarantee the complete absence of dewetting between the film of block copolymer BCP deposited and its top coat, when such an upper layer of top coat type is used.

### TECHNICAL PROBLEM

The aim of the invention is thus to overcome at least one of the disadvantages of the prior art. The invention is targeted in particular at providing a simple alternative solution which can be carried out industrially for controlling the orientation of the nanodomains of any block copolymer, so that the nanodomains orientate themselves perpendicularly to the substrate and to the upper interface, over a minimum thickness “t” at least equal to a half-period L₀ of the block copolymer, this being done without using a specific layer of top coat type which is neutral for the block copolymer BCP.

The invention is additionally targeted at stabilizing the film of block copolymer deposited on a substrate neutralized beforehand, with regard to the wetting phenomena possible with the substrate.

### BRIEF DESCRIPTION OF THE INVENTION

To this end, a subject-matter of the invention is a process for controlling the orientation of the nanodomains of a block copolymer, the lower interface of which is in contact with the surface, neutralized beforehand, of a substrate, the said block copolymer being capable of nanostructuring itself to give nanodomains with a predetermined period, over a minimum thickness at least equal to half of the said period, the said process being characterized in that it consists in depositing the said block copolymer on the said substrate, so that its total thickness is at least two times greater than the said minimum thickness and preferably at least three times greater than the said minimum thickness, and in then depositing, on the said block copolymer, an interface material which makes it possible to isolate it from the ambient atmosphere.

Thus, the interface material deposited on the upper interface of the block copolymer exhibits a specific affinity with at least one of the blocks of the block copolymer, this affinity being less marked than that of the ambient atmosphere. The excess thickness of block copolymer, which excess thickness is deposited above the minimum thickness, for its part makes it possible to compensate for the preferred affinity of one of the blocks of the block copolymer with the component of the interface material. Furthermore, this sizeable excess thickness also makes it possible to stabilize the film of block copolymer BCP deposited with regard to the dewetting phenomena possible with the neutralized substrate. Thus, the excess thickness makes it possible to allow, for example, a higher annealing temperature/assembling time pair, or else to slow down the kinetics of dewetting or to eliminate them completely.

According to other optional characteristics of the process for controlling the surface energy and the orientation of the nanodomains of a block copolymer:
the minimum thickness, over which the said block copolymer is intended to nanostructure itself, is chosen so as to be equal to an integral or half-integral multiple of the period (L₀), the said multiple being less than or equal to 15 and preferably less than or equal to 10;
a stage subsequent to the deposition of the block copolymer consists in carrying out the self-organization of the block copolymer, so as to nanostructure it over at least the said minimum thickness;
the self-organization of the block copolymer can be carried out by any appropriate technique or combination of appropriate techniques known to a person skilled in the art, the preferred technique being the heat treatment:
the upper interface of the block copolymer is in contact with an interface material comprising a compound, or mixture of compounds, of defined molecular constitution and of defined surface energy, which can be solid or liquid at the temperature of organization of the said block copolymer, and which makes it possible to isolate the film of block copolymer from the influence of the ambient atmosphere or of a defined mixture of gases;
the said compound, or mixture of compounds, exhibits a specific affinity with at least one of the blocks of the block copolymer;
the said compound of the upper interface material, in contact with the block copolymer, is chosen so that its surface energy is at least greater than the value “γᵢ−5” (in mN/m) and at least less than the value “γₛ+5” (in mN/m), where γᵢ represents the lowest value of the surface energy among all the values of each of the blocks of the block copolymer and where γₛ represents the greatest value of the surface energy among all the values of each of the blocks of the block copolymer;
preferably, the said compound of the upper interface material, in contact with the block copolymer, is chosen so that its surface energy is between the values γᵢ and γₛ;
the said compound of the upper interface material is chosen so as not to be neutral with regard to each of the blocks of the block copolymer;
the said compound of the upper interface material is chosen as being neutral with regard to each of the blocks of the block copolymer;
the substrate does or does not comprise patterns, the said patterns being predrawn by a lithography stage or a sequence of lithography stages of any nature prior to the stage of deposition of the film of block copolymer, the said patterns being intended to guide the organization of the said block copolymer by a technique referred to as chemical epitaxy or graphoepitaxy, or else a combination of these two techniques, in order to obtain a neutralized surface.

An additional subject-matter of the invention is a process for the manufacture of a nanolithography resist starting from a block copolymer, the lower interface of which is in contact with a surface, neutralized beforehand, of an underlying substrate, the said process comprising the stages of the process for controlling the orientation of the nanodomains of a block copolymer as described above and being characterized in that, after the nanostructuring of the block copolymer, the interface material and also an excess thickness of the said block copolymer are removed, in order to leave a film of block copolymer nanostructured perpendicularly with respect to the said substrate over the said minimum thickness (t), and then at least one of the blocks of the said film of block copolymer is removed, in order to form a porous film capable of acting as nanolithography resist.

According to other optional characteristics of the process for the manufacture of a resist:
the removal of the interface material and the removal of the said excess thickness of the said block copolymer are carried out simultaneously or sequentially;
the stage(s) of removal of the interface material and of the excess thickness is (are) carried out by a treatment of chemical mechanical polishing (CMP), solvent, ion bombardment or plasma type or by any combination, carried out sequentially or simultaneously, of the said treatments;
the stage(s) of removal of the interface material and of the excess thickness is (are) carried out by plasma dry etching;
the stage of removal of one or more blocks of the said film of block copolymer is carried out by dry etching;
the stages of removal of the interface material, of the excess thickness and of removal of one or more blocks of the film of block copolymer are carried out successively in one and the same etching machine, by plasma etching;
the block copolymer can be subjected, in all or part, to a crosslinking/curing stage prior to the stage of removal of the said excess thickness:
the crosslinking/curing stage is carried out by exposure of the block copolymer to light radiation of defined wavelength chosen from ultraviolet radiation, ultraviolet/visible radiation or infrared radiation, and/or electron radiation, and/or a chemical treatment, and/or an atom or ion bombardment.

Finally, a subject-matter of the invention is a nanolithography resist obtained in accordance with the process described above.

Other distinctive features and advantages of the invention will become apparent on reading the description given by way of illustrative and non-limiting example, with reference to the appended Figures, which represent:

FIG. 1, already described, a diagram seen in section of a block copolymer, deposited on a substrate, the surface of which has been neutralized by producing a chemically epitaxied pattern, before and after the annealing stage necessary for its self-assembling, when the surface energy at the upper interface is not controlled,

FIG. 2, already described, a diagram seen in section of a block copolymer, deposited on a substrate, the surface of which has been neutralized by producing a chemically epitaxied pattern, before and after the annealing stage necessary for its self-assembling, when the block copolymer is covered with a specific upper layer for surface neutralization prior to the annealing stage,

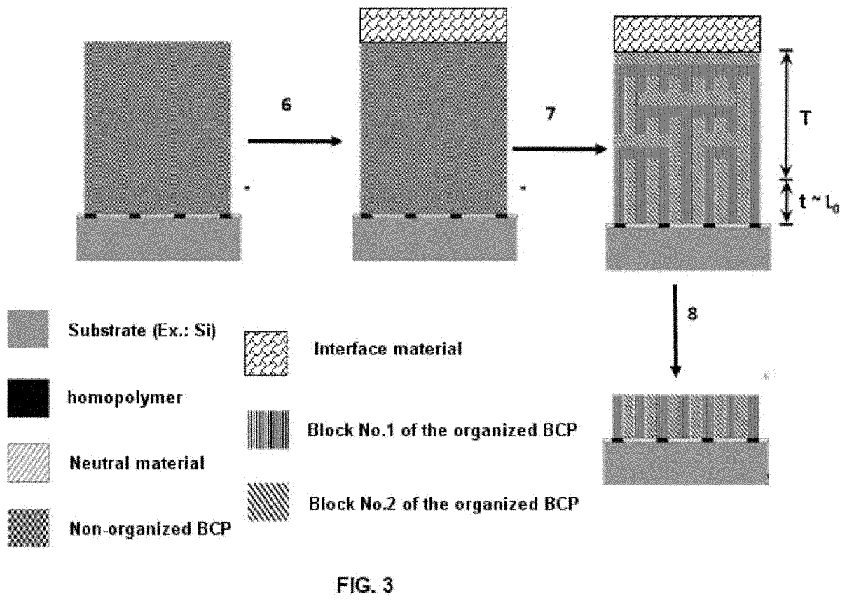

FIG. 3, a diagram seen in section of a block copolymer comprising different stages of a process according to the invention for controlling the orientation of the nanodomains of a block copolymer, the said process making it possible for the block copolymer to nanostructure itself so that its nanodomains are oriented perpendicularly to the surface of the substrate over a minimum thickness “t”.

### DETAILED DESCRIPTION OF THE INVENTION

The term “polymers” is understood to mean either a copolymer (of statistical, gradient, block or alternating type) or a homopolymer.

The term “monomer” as used relates to a molecule which can undergo a polymerization.

The term “polymerization” as used relates to the process for conversion of a monomer or of a mixture of monomers into a polymer.

The term “copolymer” is understood to mean a polymer bringing together several different monomer units.

The term “statistical copolymer” is understood to mean a copolymer in which the distribution of the monomer units along the chain follows a statistical law, for example of Bernoulli (zero-order Markov) or first-order or second-order Markov type. When the repeat units are distributed at random along the chain, the polymers have been formed by a Bernoulli process and are referred to as random copolymers. The term “random copolymer” is often used even when the statistical process which has prevailed during the synthesis of the copolymer is not known.

The term “gradient copolymer” is understood to mean a copolymer in which the distribution of the monomer units varies progressively along the chains.

The term “alternating copolymer” is understood to mean a copolymer comprising at least two monomer entities which are distributed alternately along the chains.

The term “block copolymer” is understood to mean a polymer comprising one or more uninterrupted sequences of each of the separate polymer entities, the polymer sequences being chemically different from one another and being bonded to one another via a chemical (covalent, ionic, hydrogen or coordination) bond. These polymer sequences are also known as polymer blocks. These blocks exhibit a phase segregation parameter (Flory-Huggins interaction parameter) such that, if the degree of polymerization of each block is greater than a critical value, they are not miscible with one another and separate into nanodomains.

The above term “miscibility” is understood to mean the ability of two or more compounds to mix completely to form a homogeneous or “pseudo-homogeneous” phase, that is to say a phase without apparent short-range or long-range crystal or quasi-crystal symmetry. The miscible nature of a mixture can be determined when the sum of the glass transition temperatures (Tg) of the mixture is strictly less than the sum of the Tg values of the compounds taken in isolation.

In the description, reference is made both to “self-assembling” and to “self-organization” or else to “nanostructuring” to describe the well-known phenomenon of phase separation of the block copolymers, at an assembling temperature also known as annealing temperature.

The term “period of a block copolymer”, denoted L₀, is understood to mean the minimum distance separating two neighbouring domains having the same chemical composition, separated by a domain having a different chemical composition.

Minimum thickness “t” is understood to mean the thickness of a film of block copolymer acting as nanolithography resist, below which it is no longer possible to transfer the patterns of the film of block copolymer into the underlying substrate. In general, for the block copolymers having a high phase segregation parameter χ, this minimum thickness “t” is at least equal to half the period L₀ of the block copolymer.

The term “porous film” denotes a film of block copolymer from which one or more nanodomains have been removed, leaving holes, the shapes of which correspond to the shapes of the nanodomains which have been removed and which can be spherical, cylindrical, lamellar or helical.

“Neutral” or “pseudo-neutral” surface is understood to mean a surface which, in its overall nature, does not exhibit a preferred affinity with one of the blocks of a block copolymer. It thus makes possible an equitable or “pseudo-equitable” distribution of the blocks of the block copolymer at the surface.

The neutralization of the surface of a substrate makes it possible to obtain such a “neutral” or “pseudo-neutral” surface.

When reference is made to the surface energies or more specifically to the interfacial tensions of a material and of a block of a given block copolymer, these are compared at a given temperature and more particularly at a temperature which makes possible the self-organization of the block copolymer.

The term “lower interface” of a block copolymer to be nanostructured is understood to mean the interface in contact with an underlying substrate on which the said block copolymer is deposited. It should be noted that, throughout the continuation of the description, this lower interface is neutralized, that is to say that it does not exhibit, in its overall nature, a preferred affinity with one of the blocks of the block copolymer.

The term “upper interface” or “upper surface” of a block copolymer to be nanostructured is understood to mean the interface in contact with a compound or mixture of compounds of defined molecular constitution and of defined surface energy, whether it is solid or liquid, that is to say non-volatile, at the temperature of self-organization of the nanodomains. Thus, when the compound is liquid, this can be a solvent or mixture of solvents in which the block copolymer is insoluble. When the compound is solid, this can, for example, be a copolymer, the affinity of which with at least one of the blocks of the block copolymer is less marked than with the ambient air.

As regards the film of block copolymer to be nanostructured, denoted BCP in the continuation of the description, it comprises “n” blocks, n being any integer greater than or equal to 2. The block copolymer BCP is more particularly defined by the following general formula:

A-b-B-b-C-b-D-b- -b-Z

where A, B, C, D, . . . , Z are blocks “i” . . . “j” representing either pure chemical entities, that is to say that each block is a set of monomers of identical chemical natures, polymerized together, or a set of comonomers, copolymerized together, in the form, in all or part, of a block or statistical or random or gradient or alternating copolymer.

Each of the blocks “i” . . . “j” of the block copolymer BCP to be nanostructured can thus potentially be written in the form: i=aᵢ-co-bᵢ-co- . . . -co-zᵢ, with i≠ . . . ≠j, in all or part.

The volume fraction of each entity aᵢ . . . zᵢ can range from 1% to 99%, as monomer units, in each of the blocks i . . . j of the block copolymer BCP.

The volume fraction of each of the blocks i . . . j can range from 5% to 95% of the block copolymer BCP.

The volume fraction is defined as being the volume of an entity with respect to that of a block, or the volume of a block with respect to that of the block copolymer.

The volume fraction of each entity of a block of a copolymer, or of each block of a block copolymer, is measured in the way described below. Within a copolymer in which at least one of the entities, or one of the blocks, if a block copolymer is involved, comprises several comonomers, it is possible to measure, by proton NMR, the molar fraction of each monomer in the entire copolymer and then to work back to the mass fraction by using the molar mass of each monomer unit. In order to obtain the mass fractions of each entity of a block, or each block of a copolymer, it is then sufficient to add the mass fractions of the constituent comonomers of the entity or of the block. The volume fraction of each entity or block can subsequently be determined from the mass fraction of each entity or block and from the density of the polymer forming the entity or the block. However, it is not always possible to obtain the density of the polymers, the monomers of which are copolymerized. In this case, the volume fraction of an entity or of a block is determined from its mass fraction and from the density of the compound which is predominant by weight in the entity or in the block.

The molecular weight of the block copolymer BCP can range from 1000 to 500 000 g.mol⁻¹.

The block copolymer BCP can exhibit any type of architecture: linear, star-branched (three or multiple arms), grafted, dendritic or comb.

As regards the process for controlling the orientation of the nanodomains of the block copolymer BCP, itself deposited beforehand on an underlying substrate, the surface of which has been neutralized beforehand, the principle of the invention consists in using the preferred affinity of one of the blocks of the block copolymer BCP for the material (liquid, solid, polymer, and the like) of the upper interface, rather than preferred affinity with the ambient atmosphere, in combination with a high thickness of the said block copolymer BCP, in order to simultaneously efficiently screen this preferred affinity from the lower parts of the film of block copolymer and to stabilize the film of block copolymer with regard to a possible phenomenon of dewetting of the substrate, in order to orientate the nanodomains of the block copolymer along a desired direction, over a minimum thickness (t), during the stage of nanostructuring the said block copolymer BCP.

The underlying substrate can be a solid of inorganic, organic or metallic nature. In a specific example, it can be made of silicon. Its surface is neutralized beforehand. For this, the substrate does or does not comprise patterns, the said patterns being predrawn by a lithography stage or a sequence of lithography stages of any nature prior to the stage of deposition of the film of block copolymer BCP, the said patterns being intended to guide the organization of the said block copolymer BCP by a technique referred to as chemical epitaxy or graphoepitaxy, or else a combination of these two techniques, in order to obtain the neutralized surface.

The block copolymer is capable of nanostructuring itself into nanodomains with a period (L₀) over a minimum thickness (t) at least equal to half of the said period (L₀).

In order to neutralize the upper interface, the block copolymer is advantageously deposited on the said substrate with a total thickness (T+t), representing the sum of the said minimum thickness (t) and of an excess thickness (T), which is at least two times greater than the said minimum thickness (t). Subsequently, any thickness of a liquid or solid material exhibiting a specific affinity, even if this is slight, for at least one of the blocks of the block copolymer BCP is deposited on the film of block copolymer BCP, in order to isolate the said BCP film from the ambient atmosphere or from a defined mixture of gases.

The latter stage, referenced 6 in the diagram of FIG. 3, of deposition of an intermediate “buffer” layer, also known as interface material in the continuation of the description, between the block copolymer BCP and the ambient atmosphere, constitutes the core of this invention as it is then possible to choose another compound at the upper interface of the block copolymer which exhibits a specific affinity with at least one of the blocks of the block copolymer, this affinity being less marked than that of the ambient air. This compound at the upper interface can, for example, be a solid, such as a copolymer, for example, or a liquid, such as a solvent, in which the block copolymer BCP is insoluble, or else an ionic liquid. This process exhibits the enormous advantage, with respect to the top coat process of the prior art, of not using an upper material which is neutral for the blocks of the block copolymer BCP but which makes it possible instead to greatly decrease the block copolymer BCP/initial atmosphere affinity.

More preferably, the total thickness (T+t) is at least three times greater than the said minimum thickness (t).

The minimum thickness (t) represents the thickness over which the block copolymer has to nanostructure itself in order to be able to subsequently etch patterns in the underlying substrate by virtue of the nanostructured block copolymer, which acts as nanolithography resist. For a copolymer having a high phase segregation parameter, this minimum thickness (t) is at least equal to half the nanostructuring period (L₀) of the block copolymer.

FIG. 3 illustrates stage 6 of deposition of the block copolymer BCP on the surface, neutralized beforehand by chemical epitaxy, of the substrate and of a layer of interface material intended to act as “buffer” layer between the block copolymer, deposited beforehand, and the atmosphere. This interface material is provided in the solid or liquid form. The block copolymer BCP is advantageously deposited over a total thickness (T+t). The interface material and also the excess thickness “T” of the block copolymer BCP then make it possible to screen and protect the minimum thickness “t” of the block copolymer BCP from the influence of the preferred affinity of the atmosphere with one of the blocks of the said block copolymer. Thus, the air in contact with the interface material deposited on the upper surface of the block copolymer BCP does not have an influence into the depth of the copolymer and in particular over the minimum thickness “t”. The process for controlling the orientation of the nanodomains of a block copolymer according to the invention is thus universal and applies whatever the chemical system of the block copolymer.

The minimum total thickness (T+t) of the block copolymer BCP is chosen so that: (T+t)≥2t, and preferably (T+t)≥3t, with “t” at least equal to half of L₀.

In addition, the invention is not limited to obtaining a minimum thickness “t” of the order of half of the period L₀. This is because this minimum thickness can advantageously be chosen so that it is equal to an integral or half-integral multiple of the period (L₀), the said multiple being less than or equal to 15 and preferably less than or equal to 10. Thus, if it is desired to organize the nanodomains of a block copolymer perpendicularly to the lower and upper interfaces, over a minimum thickness “t” equal to 2L₀, for example, it is advisable to deposit the block copolymer over a total thickness (T+t) of at least 4L₀ to 6L₀ (=2t to 3t). In the same way, if it is desired to organize the nanodomains of a block copolymer perpendicularly to the lower and upper interfaces, over a minimum thickness “t” equal to 3L₀, for example, it is advisable to deposit the block copolymer over a total thickness (T+t) of at least 6L₀ to 9L₀ (=2t to 3t).

The compound at the upper interface, in contact with the block copolymer BCP, can be chosen so that its surface energy is at least greater than the value “γᵢ−5” (in mN/m) and at least less than the value “γₛ+5” (in mN/m), where γᵢ represents the lowest value of the surface energy among all the values of each of the blocks of the block copolymer and where γₛ represents the greatest value of the surface energy among all the values of each of the blocks of the block copolymer BCP. Preferably, the compound at the upper interface, in contact with the block copolymer, is chosen so that its surface energy is between the values γᵢ and γₛ. The compound at the upper interface can be chosen so as not to be neutral with regard to each of the blocks of the block copolymer.

The block copolymer can be deposited according to techniques known to a person skilled in the art, such as, for example, the spin coating, doctor blade, knife system or else slot die system technique. For this, the block copolymer BCP is mixed beforehand in a solvent.

A stage subsequent to the deposition of the block copolymer BCP and to the deposition of the upper interface material consists in proceeding to the self-organization of the block copolymer BCP so that it nanostructures itself over at least the minimum thickness “t” (stage referenced 7 in the diagram of FIG. 3). For this, the self-organization of the block copolymer can be carried out by any appropriate technique or combination of appropriate techniques known to a person skilled in the art. Preferably, it is carried out by submitting the stack obtained, comprising the substrate, the surface of which has been neutralized beforehand, the block copolymer BCP and the interface material, to a heat treatment. The block copolymer then nanostructures itself under the effect of the heat treatment and the nanodomains obtained orientate themselves perpendicularly to the surface of the substrate over at least the said minimum thickness “t”.

As regards the process for the manufacture of a nanolithography resist, when the block copolymer BCP is nanostructured and when its patterns are oriented perpendicularly to the surface of the substrate, over at least the said minimum thickness “t”, it is advisable to proceed first to the removal of the material of the upper interface and then to the removal of the excess thickness “T” (stage 8 of FIG. 3), in order to obtain a film of block copolymer BCP which is nanostructured. This film is intended to act as a resist in a subsequent nanolithography process, in order to transfer its patterns into the underlying substrate.

For this, the removal of the upper interface material and also the removals of the excess thickness “T” of the block copolymer can be carried out, simultaneously or sequentially, by a treatment of chemical mechanical polishing (CMP), solvent, ion bombardment or plasma type or by any combination, carried out sequentially or simultaneously, of these treatments.

Preferably, the removals of the upper interface material and of the excess thickness “T” of the block copolymer are carried out by dry etching, such as plasma etching, for example, for which the chemistry (chemistries) of the gas(es) employed is (are) chosen so as not to exhibit a specific selectivity for a given block of the block copolymer BCP. Thus, the etching takes place at the same rate for all the blocks of the block copolymer BCP. The etching of the excess thickness “T” is thus carried out until the said minimum thickness “t”, chosen beforehand, of block copolymer BCP is left on the substrate.

In one example, the block copolymer is, for example, deposited over a total thickness (T+t) at least greater than 50 nm, and the upper interface material and also the excess thickness “T” are removed in order to retain a minimum thickness “t” of less than 45 nm, preferably of less than 40 nm. This case can, for example, exist with a block copolymer with a period L₀ equal to 20 nm and for which a minimum thickness “t” equal to L₀ or to 2L₀, for example, is desired.

Prior to the removal of the excess thickness T, the block copolymer can be subjected, in all or part, to a crosslinking/curing stage. In such a case, the removal of the interface material will be carried out before the removal of the excess thickness T, in order to be able to crosslink/cure all or part of the block copolymer.

This crosslinking/curing stage can be carried out by exposure of the block copolymer BCP to light radiation of defined wavelength chosen from ultraviolet radiation, ultraviolet/visible radiation or infrared radiation, and/or electron radiation, and/or a chemical treatment, and/or an atom or ion bombardment.

After removal of the upper interface material and of the said excess thickness T, a film of block copolymer BCP nanostructured over a thickness “t” is then obtained, the nanodomains of which are oriented perpendicularly to the surface of the underlying substrate, as represented in the diagram of FIG. 3. This film of block copolymer is then capable of acting as resist, after removal of at least one of its blocks in order to leave a porous film and to thus be able to transfer its patterns into the underlying substrate by a nanolithography process.

The removal of the block or blocks of the film of block copolymer can be carried out by any known means, such as wet etching, using a solvent capable of dissolving the block(s) to be removed while retaining the other blocks, or dry etching.

When wet etching is chosen, prior to the removal of the block or blocks of the film of block copolymer which remains, it is possible to apply a stimulus to all or part of the said film of block copolymer. Such a stimulus can, for example, be produced by exposure to UV-visible radiation, to an electron beam or else to a liquid exhibiting acid/base or oxidation/reduction properties, for example. The stimulus then makes it possible to induce a chemical modification over all or part of the block copolymer BCP, by cleaving of polymer chains, formation of ionic entities, and the like. Such a modification then facilitates the dissolution of one or more blocks of the copolymer to be removed, in a solvent or mixture of solvents, in which the other blocks of the copolymer BCP are not soluble before or after the exposure to the stimulus.

In one example, if the block copolymer intended to act as resist is a PS-b-PMMA block copolymer, a stimulus by exposure of the film of block copolymer to UV radiation will make it possible to cleave the polymer chains of the PMMA while bringing about crosslinking of the chains of PS polymers. In this case, the PMMA patterns of the block copolymer can be removed by dissolution in a solvent or mixture of solvents judiciously chosen by a person skilled in the art.

Another way of removing one or more block(s) of the film of block copolymer consists in using dry etching, such as plasma etching, for example. Such a plasma etching is preferred as it can be carried out in the same machine as the stage(s) of removal of the interface material and of removal of the excess thickness “T”; only the chemistry of the constituent gases of the plasma has to be changed in order to be able to selectively remove the block(s) to be removed and to retain the other blocks.

Likewise, another advantage of this plasma etching lies in the fact that the removal of the upper interface material, the removal of the excess thickness “T”, the removal of the block(s) of the film of block copolymer and then the transfer of the patterns of the film of block copolymer into the underlying substrate can be carried out in the same etching machine. In this case, only the chemistry of the gases of the plasma will or will not have to be changed, depending on the materials to be removed.

1. A process for controlling the surface energy at the upper interface of a block copolymer (BCP), the lower interface of which is in contact with the surface, neutralized beforehand, of a substrate, the block copolymer being capable of nanostructuring itself to give nanodomains with a predetermined period (L₀), over a minimum thickness (t) at least equal to half of the period (L₀), the process comprising depositing the said block copolymer (BCP) on the substrate, so that its total thickness (T+t) is at least two times greater and than the minimum thickness (t), the minimum thickness being chosen so as to be equal to an integral or half-integral multiple of the period (L₀), the multiple being less than or equal to 15, and then depositing, on the block copolymer (BCP), an interface material exhibiting a preferred affinity, with one of the blocks of the block copolymer, which is less than the preferred affinity which the ambient atmosphere exhibits.

2. The process according to claim 1, wherein a stage subsequent to the deposition of the block copolymer (BCP) consists in carrying out the self-organization of the block copolymer (BCP), so as to nanostructure it over at least the minimum thickness (t).

3. The process according to claim 1, wherein the upper interface of the block copolymer is in contact with an interface material comprising a compound, or mixture of compounds, of defined molecular constitution and of defined surface energy, which can be solid or liquid at the temperature of organization of the block copolymer, and which makes it possible to isolate the film of block copolymer (BCP) from the influence of the ambient atmosphere or of a defined mixture of gases.

4. The process according to claim 3, wherein the compound, or mixture of compounds, exhibits a specific affinity with at least one of the blocks of the block copolymer (BCP).

5. The process according to claim 3, wherein the compound of the upper interface material, in contact with the block copolymer (BCP), is chosen so that its surface energy is at least greater than the value “γᵢ−5” (in mN/m) and at least less than the value “γₛ+5” (in mN/m), where γᵢ represents the lowest value of the surface energy among all the values of each of the blocks of the block copolymer (BCP) and where γₛ represents the greatest value of the surface energy among all the values of each of the blocks of the block copolymer (BCP).

6. The process according to claim 5, wherein the compound of the upper interface material, in contact with the block copolymer (BCP), is chosen so that its surface energy is between the values γᵢ and γₛ.

7. The process according to claim 3, wherein compound of the upper interface material is chosen so as not to be neutral with regard to each of the blocks of the block copolymer (BCP).

8. The process according to claim 3, wherein the compound of the upper interface material is chosen as being neutral with regard to each of the blocks of the block copolymer (BCP).

9. The process according to claim 1, wherein the substrate does or does not comprise patterns, the patterns being predrawn by a lithography stage or a sequence of lithography stages of any nature prior to the stage of deposition of the film of block copolymer (BCP), the patterns being intended to guide the organization of the block copolymer (BCP) by a technique referred to as chemical epitaxy or graphoepitaxy, or else a combination of these two techniques, in order to obtain a neutralized surface.

10. A process for the manufacture of a nanolithography resist starting from a block copolymer (BCP), the lower interface of which is in contact with a surface, neutralized beforehand, of an underlying substrate, the process comprising the stages of the process for controlling the orientation of the nanodomains of a block copolymer (BCP) according to claim 1, wherein after the nanostructuring of the block copolymer (BCP), the interface material and also an excess thickness (T) of the block copolymer are removed, in order to leave a film of block copolymer nanostructured perpendicularly with respect to the substrate over the minimum thickness (t), and then at least one of the blocks of the said film of block copolymer is removed, in order to form a porous film capable of acting as a nanolithography resist.

11. The process according to claim 10, wherein the removal of the interface material and the removal of the excess thickness (T) of the block copolymer are carried out simultaneously or sequentially.

12. The process according to claim 10, wherein the stage(s) of removal of the interface material and of the excess thickness (T) is (are) carried out by a treatment of chemical mechanical polishing (CMP), solvent, ion bombardment or plasma type or by any combination, carried out sequentially or simultaneously, of the treatments.

13. The process according to claim 10, wherein the stage(s) of removal of the interface material and of the excess thickness (T) is (are) carried out by plasma dry etching.

14. The process according to claim 10, wherein the stage of removal of one or more blocks of the film of block copolymer is carried out by dry etching.

15. The process according to claim 10, wherein the stages of removal of the interface material, of the excess thickness (T) and of removal of one or more blocks of the film of block copolymer are carried out successively in one and the same etching machine, by plasma etching.

16. The process according to claim 10, wherein the block copolymer (BCP) can be subjected, in all or part, to a crosslinking/curing stage prior to the stage of removal of the excess thickness (T).

17. The process according to claim 16, wherein the crosslinking/curing stage is carried out by exposure of the block copolymer (BCP) to light radiation of defined wavelength chosen from ultraviolet radiation, ultraviolet/visible radiation or infrared radiation, and/or electron radiation, and/or a chemical treatment, and/or an atom or ion bombardment.
